(19) United States
(12) Patent Application Publication
(10) Pub. No.: US 2011/0107592 A1
(43) Pub. Date: May 12, 2011

(54) HOLDING MECHANISM FOR ELECTRICAL CONNECTORS AND PCBS

(75) Inventors: Sung-Lin Chen, Taipei Hsien (TW); Xiao-Lin Wu, Taipei Hsien (TW); Shaobo Zhang, Taipei Hsien (TW); Zai-Wei Zou, Taipei Hsien (TW); Jun Ma, Taipei Hsien (TW)

(73) Assignee: CHENG UEI PRECISION INDUSTRY CO., LTD., Taipei Hsien (TW)

(21) Appl. No.: 12/615,388

(22) Filed: Nov. 10, 2009

(51) Int. Cl. H05K 13/00; B23P 19/00

(52) U.S. Cl. 29/760

(57) ABSTRACT

A holding mechanism has a holding component including a base and a covering plate. The covering plate has two supporting pegs at two ends of a bottom thereof fixed on a top surface of the base, for forming a receiving chamber where a plurality of electrical connectors, with PCBs inserted therein, is arranged side by side. A stopping plate is capable of being driven to insert into and withdraw from the receiving chamber from a frontward direction, for resting front ends of the electrical connectors. A locking component is capable of moving frontward and rearward, and has a main body disposed rearward of the base. The main body has an upper portion protruded frontward to form a locking portion, for resting rear ends of the PCBs, and a plurality of pressing elements extending frontward above and beyond the locking portion, for pressing exposed top surfaces of the inserted PCBs.

### BACKGROUND OF THE INVENTION

1. Field of the Invention

The present invention relates to a holding mechanism, and particularly to a holding mechanism which is capable of fixing a plurality of electrical connectors and printed circuit boards (PCBs).

2. The Related Art

With the ever-increasing development of electronic technology, various electronic devices come into exist in daily life and are constantly renewed toward multifunction and miniaturization for meeting the demands of the users. Consequently, electrical connectors, with compact and small configurations, serving as transitional connection devices, are widely used. But, since the electrical connector is complicated and small, it is difficult and time-consuming to assemble the electrical connector, especially, some processes are important and require precise operation, for preventing from affecting quality of the electrical connector, such as soldering terminals to a printed circuit board (PCB).

FIG. 1 and FIG. 2 are perspective views showing an electrical connector 80 in prior art. The electrical connector 80 includes an insulating housing 81, a plurality of terminals 82 mounted to the insulating housing 81 and a shell 83 coupled with the insulating housing 81. The terminals 82 have distal ends projecting outside the insulating housing 81 and spaced away from the shell 83. A PCB 90 is provided to insert a gap between the distal ends of the terminals 82 and the shell 83. The distal ends of the terminals 82 are soldered on corresponding soldering areas 91 of the PCB 90 for achieving electrical connection. However, in conventional soldering process, the operator has to fix the terminals 82 with respect the PCB 90 in a manual manner, and solders the distal ends of the terminals 82 to the soldering areas 91 at the same time. Since the electrical connector 80 and the PCB 90 are too small, it is necessary and demanded for the operator to have high-level solder technique and pay great attention. If there is any careless, there result in the soldering failure between the electrical connector 80 and the PCB 90, which not only affects the performance of the electronic connector 80, but also delays the subsequent assembling process. Therefore, it is an urgently solved problem to reduce the solder difficulty and improve solder efficiency of the small electrical connectors.

### SUMMARY OF THE INVENTION

Accordingly, an object of the present invention is to provide a holding mechanism. The holding mechanism is adapted for fixing a plurality of electrical connectors where a plurality of PCBs is correspondingly inserted from a rearward direction, and has a holding component. The holding component has a rectangular base and a covering plate mounted above the base. The covering plate has two supporting pegs at two ends of a bottom thereof. The supporting pegs are fixed on a top surface of the base, for forming a receiving chamber where the electrical connectors are arranged side by side to form a row perpendicular to a front and rear direction. A stopping plate is capable of being driven to insert into and withdraw from the receiving chamber from a frontward direction, for resting against front ends of the electrical connectors. A locking component is capable of moving frontward and rearward, and has a main body disposed rearward of the base. The main body has an upper portion protruded frontward to form a locking portion, for resting against rear ends of the inserted PCBs, and a plurality of pressing elements extending frontward above and beyond the locking portion, for pressing exposed top surfaces of the inserted PCBs.

As described above, the holding component provides the receiving chamber for receiving the plural electrical connectors and the corresponding PCBs. The stopping plate is capable of moving with respect to the holding component and fixing the electrical connectors from the frontward direction. The locking component is capable of moving with respect to the holding component and fixing the PCBs from the rearward direction and the up direction. Thus the electrical connectors and the PCBs are fixed firmly, which addresses the problem that the operator manually fixes the electrical connector and the PCB in soldering process, thereby reducing the solder difficulty and improving the solder quality. Meanwhile, the holding mechanism is capable of fixing the plural electrical connectors and the PCBs at one time, which is excellent to raise the solder efficiency.

### BRIEF DESCRIPTION OF THE DRAWINGS

The present invention will be apparent to those skilled in the art by reading the following description thereof, with reference to the attached drawings, in which:

FIG. 1 is an assembled, perspective view of a conventional electrical connector, wherein a PCB is inserted therein;

FIG. 2 is a perspective view of the electrical connector shown in FIG. 1, wherein the PCB is withdrawn therefrom;

FIG. 3 is an assembled, perspective view of a holding mechanism of an embodiment in accordance with the present invention;

FIG. 4 is an exploded, perspective view of the holding mechanism shown in FIG. 3;

FIG. 5 is an assembled, perspective view of the holding mechanism shown in FIG. 3 seen from another view, wherein the plural electrical connectors of FIG. 1 are mounted thereto;

FIG. 6 is a partly enlarged view showing an enlarged portion VI of FIG. 5;

FIG. 7 is a perspective view showing a transitional element of the holding mechanism shown in FIG. 3 seen from a bottom view; and

FIG. 8 is a perspective view showing the state that the holding mechanism shown in FIG. 5 fixes the plural electrical connectors of FIG. 1.

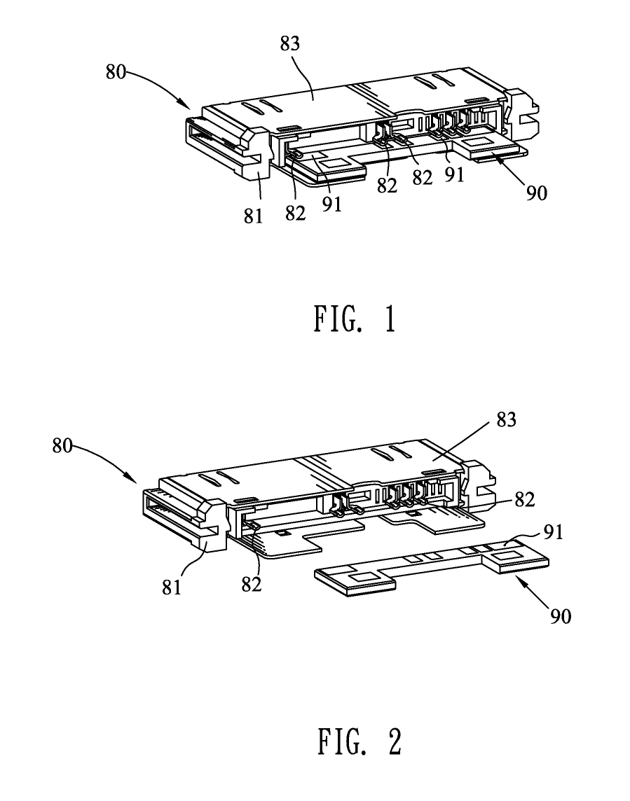

### DETAILED DESCRIPTION OF THE EMBODIMENT

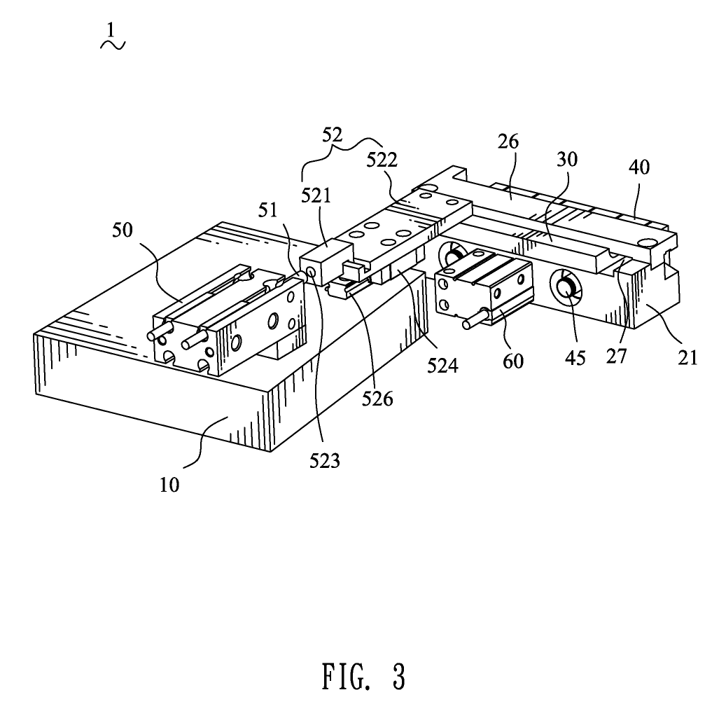

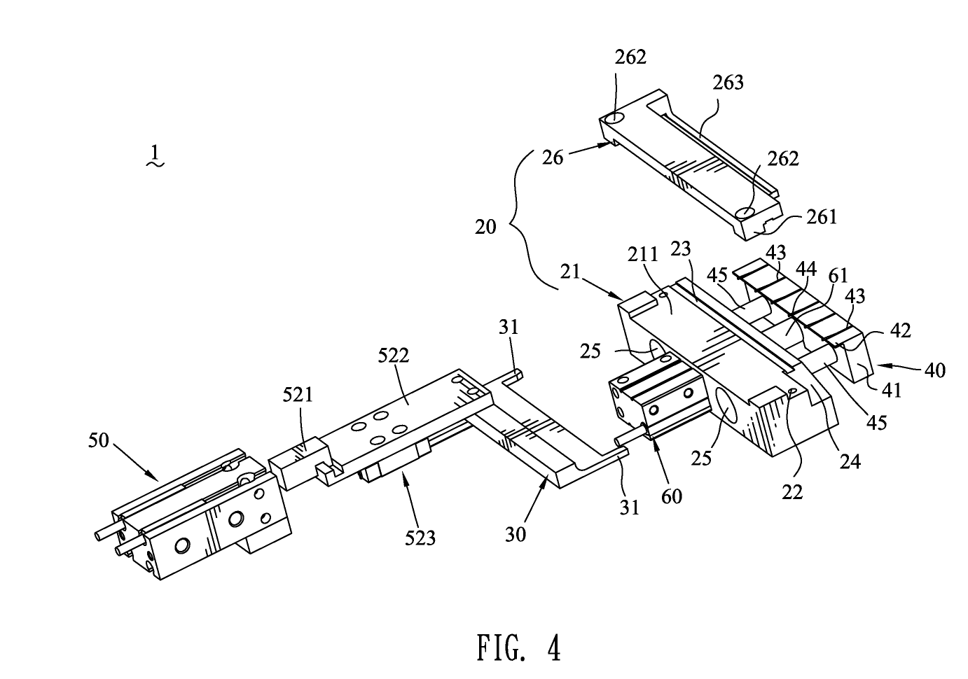

Referring to the drawings in greater detail, and first to FIGS. 3-4, the embodiment of the invention is embodied in a holding mechanism 1 which is adapted for holding a plurality of small electronic devices, such as electrical connectors, for facilitating the operation, such as solder. Hereafter, the holding mechanism 1 of this embodiment is described in detail, cooperating with the electrical connector 80 and the PCB 90 in prior art, but should not be limited.

The holding mechanism 1 comprises a supporting platform 10, a holding component 20 disposed rearward of the supporting platform 10, a stopping plate 30, a locking component 40, a first driving component 50 and a second driving component 60. The first and second driving components 50, 60 are respectively mounted to the supporting platform 10 and the holding component 20, functioned as drive. The stopping plate 30 is connected with the first driving component 50 and urged to move frontward and rearward with respect to the holding component 20. The locking component 40 is connected with the second driving component 60 and urged to move frontward and rearward with respect to the holding component 20.

With reference to FIGS. 3-5 and FIG. 8, the holding component 20 has a rectangular base 21 and a covering plate 26. The base 21 has two through holes 25 extending frontward and rearward, and defines a top surface 211. The top surface 211 has two installing holes 22 at middle portions of two opposite ends thereof, and a groove 23 disposed rearward of the installing holes 22. The groove 23 extends along a direction perpendicular to a front and rear direction for fixing the electrical connectors 80. One rear corner of the top surface 211 is formed with an inclining surface 24 for being convenient to remove the soldered electrical connectors 80. The covering plate 26 is rectangular and has two supporting pegs 261 extended downwardly from two front corners of a bottom thereof. Each of the supporting pegs 261 has a mating hole 262, corresponding to the installing hole 22. A connecting element (not shown), such as a screw, is adapted for engaging the mating hole 262 with the installing hole 22, for fixing the covering plate 26 to the base 21. The supporting pegs 261 stand on the top surface 211 of the base 21. A receiving chamber 27 is formed among the covering plate 26, the supporting pegs 261 and the top surface 211 of the base 21, for receiving the plural electrical connectors 80. The covering plate 26 further has an assistant beam 263 extending parallel to a longitudinal direction thereof. The assistant beam 263 is rearward of and lower than the covering plate 26. In assembly, the assistant beam 263 is disposed rearward of a rear surface of the base 21, with a top surface substantially flush with the top surface 211 for supporting the inserted PCBs 90. In this embodiment, the assistant beam 263 is connected with a protrusion at an end of a rear side of the covering plate 26, opposite to the inclining surface 24 for preventing from blocking the disassembly of the soldered electrical connectors 80.

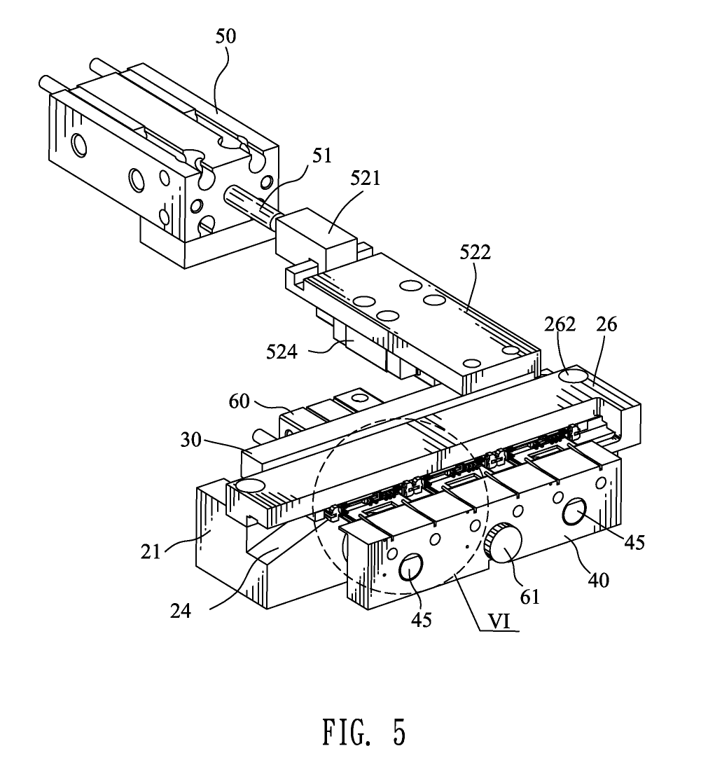

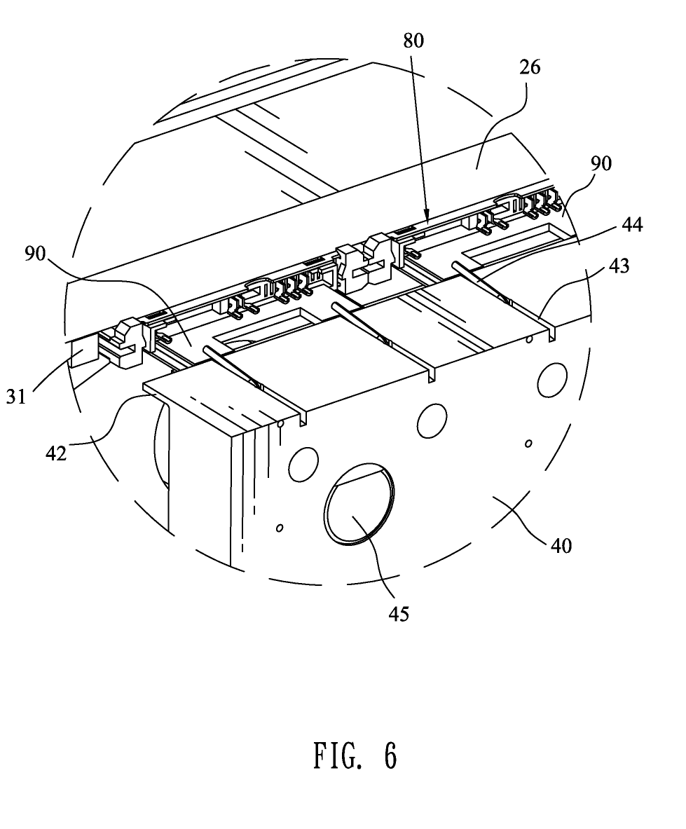

Please refer to FIGS. 4-6, the through holes 25 are spaced away from each other with a predetermined distance. A front surface of the base 21 has a recess (not shown) between the through holes 25 for partly receiving the second driving component 60. The second driving component 60 has a shaft 61 passing through the base 21 and extending rearward to connect with the locking component 40. The locking component 40 is controlled by the shaft 61 and capable of moving frontward and rearward with respect to the base 21. The locking component 40 has a main body 41 of block shape. An upper portion of the main body 41 is extended frontward to form a locking portion or locking eave 42 for resting against rear ends of the inserted PCBs 90. The locking eave 42 has a length perpendicular to the front and rear direction, substantially the same as that of the receiving chamber 27. A top surface of the locking eave 42, which is flush with a top surface of the main body 41, is formed with a plurality of slots 43 arranged at intervals and extending frontward and rearwards to pass through the top surface of the main body 41. A plurality of pressing elements or slender rods 44 are received in the slots 43, with front ends extending frontward and upwardly beyond the locking eave 42 for pressing the inserted PCBs 90 downwardly, in order to prevent from forming insufficient solder because of the unexpected shake of the inserted PCBs 90. Herein, the pressing element can also be pressing piece. The main body 41 has two parallel sliding shafts 45 extended frontward of a front surface thereof. The sliding shafts 45 are respectively inserted into the through holes 25 and slide therein for balancing the locking component 40.

Referring to FIGS. 3-4 and FIG. 6, the stopping plate 30 is substantially rectangular and has a length perpendicular to the front and rear direction, substantially the same as that of the receiving chamber 27. A rear side of the stopping plate 30 is protruded rearwards to form two clamping arms 31 at two ends thereof. In assembly, the stopping plate 30 is driven by the first driving component 50 to move in the receiving chamber 27. The rear side of the stopping plate 30 rests against front ends of the electrical connectors 80, and the clamping arms 27 are disposed to rest against two outmost sides of the electrical connectors 80, encircling the juxtaposed electrical connectors 80 for fixing the electrical connectors 80 from the frontward direction and two opposite lateral directions.

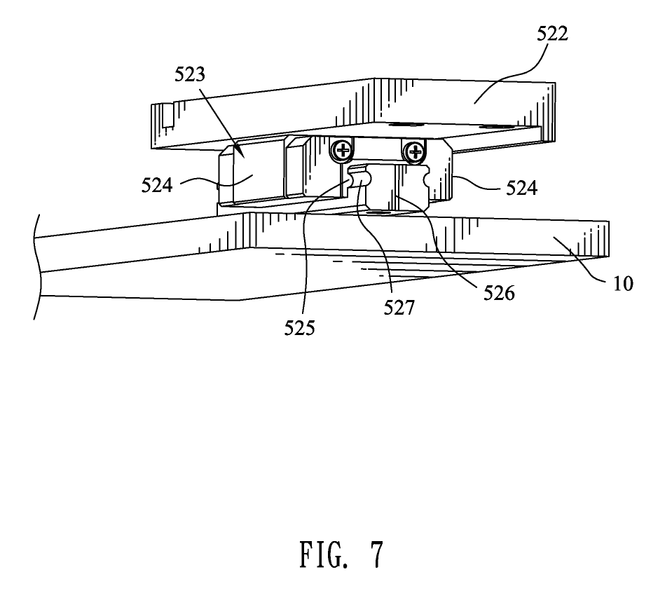

With reference to FIG. 3, FIG. 5 and FIGS. 7-8, the first driving component 50 is fixed on the supporting platform 10 and has a shaft 51 which drives the stopping plate 30 to move frontward and rearward by a transitional element 52. The transitional element 52 has a connecting block 521 connected with the shaft 51, and a connecting plate 522 connected with the connecting block 521. The connecting block 521 has a hole 523 at a front surface thereof for receiving the shaft 51. Herein the connection between the connecting block and the shaft is probably in the way of the screw thread hole coupled with the screw thread shaft, or the telescopic shaft fixed with the hole. A front end of the connecting plate 522 is connected with a rear end of the connecting block 521 in the form of recess and protrusion. In addition, it is also allowable to connect the connecting plate and the connecting block by means of other connection elements, such as screws. A slier 523 of substantially door shape is fixed under the connecting plate 522. The slider 523 defines two facing lateral walls 524, which have facing inner surfaces protruded towards each other to form guiding rails 525 extending frontward and rearwards. Accordingly, a fixing base 526 is provided and fixed on the supporting platform 10. The fixing base 526 is a rectangular block shape and received in a space surrounded by the slider 523. Two opposite sides of the fixing base 526 are formed with guiding grooves 527, corresponding to the respective guiding rails 525. The guiding rails 525 slide along the guiding grooves 527 to make the connecting plate 522 move stably and smoothly, without being affected by unexpected force or other factors. A rear end of the connecting plate 522 is fixed to the stopping plate 30. In this embodiment, the stopping plate has a front portion thicker than a rear portion which is inserted into the receiving chamber. The rear end of the connecting plate is superimposed onto and fixed to the front portion of the stopping plate.

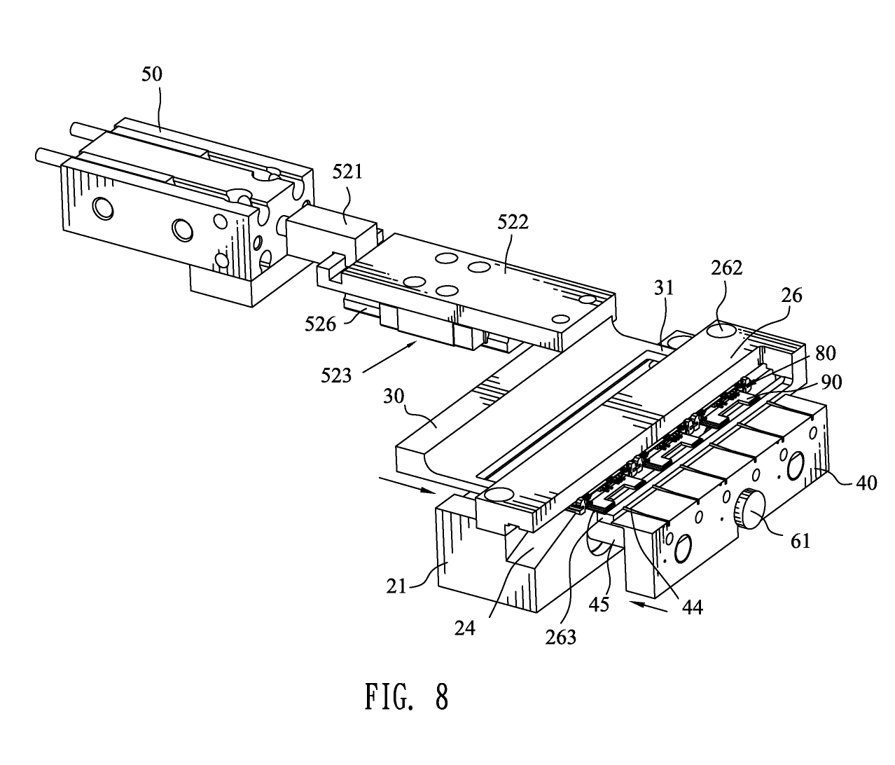

Please refer to FIG. 4 and FIG. 8, in operation, the plural electrical connectors 80, with the PCBs 90 assembled therein, are conveyed by a convey mechanism (not shown) to arrange in the receiving chamber 27 side by side to form a row. The assistant beam 263 supports the inserted PCBs 90. The first driving component 50 is work to push the stopping plate 30 to insert into the receiving chamber 27 from the frontward direction, for fixing the electrical connectors 80 from the frontward direction and the two opposite lateral directions. In the meantime, the locking component 40 is urged by the second driving component 60 to move toward the holding component 20 so that the locking eave 42 and the rods 44 fix the PCBs 90 from the rearward direction and the up direction. Thus, the plural electrical connectors 80 and the PCBs 90 are fixed firmly and allowable to execute the next procedure.

As described above, the holding component 20 provides the receiving chamber 27 for receiving the plural electrical connectors 80 and the corresponding PCBs 90. The stopping plate 30 is capable of moving with respect to the holding component 20 and fixing the electrical connectors 80 from the frontward direction and the two opposite lateral directions. The locking component 40 is capable of moving with respect to the holding component 20 and fixing the PCBs 90 from the rearward direction and the up direction. Thus the electrical connectors 80 and the PCBs 90 are fixed firmly, which addresses the problem that the operator manually fixes the electrical connector 80 and the PCB 90 in soldering process, thereby reducing the solder difficulty and improving the soldering quality. Meanwhile, the holding mechanism 1 is capable of fixing the plural electrical connectors 80 and the PCBs 90 at one time, which is excellent to raise the solder efficiency.

The foregoing description of the present invention has been presented for the purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. A holding mechanism adapted for fixing a plurality of electrical connectors where a plurality of PCBs is correspondingly inserted from a rearward direction, the holding mechanism comprising:
a holding component having a rectangular base and a covering plate mounted above the base, the covering plate having two supporting pegs at two ends of a bottom thereof, fixed on a top surface of the base, for forming a receiving chamber where the electrical connectors are arranged side by side to form a row perpendicular to a front and rear direction;
a stopping plate capable of being driven to insert into and withdraw from the receiving chamber from a frontward direction, for resting against front ends of the electrical connectors; and
a locking component capable of moving frontward and rearward, and having a main body disposed rearward of the base, the main body having an upper portion protruded frontward to form a locking portion, for resting against rear ends of the inserted PCBs, and a plurality of pressing elements extending frontward above and beyond the locking eave, for pressing exposed top surfaces of the inserted PCBs.

2. The holding mechanism as claimed in claim 1, wherein a rear end of the stopping plate is projected rearwards to form two facing clamping arms which are inserted into the receiving chamber and hug two outmost sides of the row of the electrical connectors.

3. The holding mechanism as claimed in claim 1, wherein the supporting pegs are protruded downwardly from two front corners of the rectangular covering plate, and fixed at middle portions of two opposite ends of the top surface of the base.

4. The holding mechanism as claimed in claim 3, wherein the top surface of the base has a groove extending perpendicular to the front and rear direction and rearward of the supporting pegs, for fixing the electrical connectors.

5. The holding mechanism as claimed in claim 3, wherein the top surface of the base has a rear corner formed with an inclining surface for disassembling the electrical connectors conveniently.

6. The holding mechanism as claimed in claim 1, wherein the covering plate has an assistant beam extending perpendicular to the front and rear direction, the assistant beam is disposed rearward of the base and has a top surface substantially flush with the top surface of the base, when the covering plate is mounted to the base, for supporting the inserted PCBs.

7. The holding mechanism as claimed in claim 1, wherein a top surface of the main body has a plurality of slots extending frontward and rearward and arranged at intervals, the pressing elements are slender rods, respectively received in the slots.

8. The holding mechanism as claimed in claim 1, wherein the base has two through holes extending frontward and rearwards and spaced from each other, the main body has two parallel sliding shafts extending frontward of a front surface thereof, the sliding shafts slide in the corresponding through holes when the locking component is driven to move with respect to the base, for balancing the locking component.

9. The holding mechanism as claimed in claim 8, further comprising a driving component, the driving component disposed in front of the base and having a shaft passing through the base to connect with the main body for driving the locking component to move frontward and rearwards.

10. The holding mechanism as claimed in claim 1, further comprising a first driving component, the first driving component having a shaft and a transitional element connected with the shaft, the stopping plate is connected with the transitional element for driving the stopping plate to move frontward and rearward.

11. The holding mechanism as claimed in claim 10, wherein the transitional element has a connecting block connected with the shaft, and a connecting plate connected with the connecting block, the stopping plate is connected with the connecting plate.

12. The holding mechanism as claimed in claim 11, wherein a slier of substantially door shape is fixed under the connecting plate, the slider defines two facing lateral walls, which have facing inner surfaces protruded towards each other to form guiding rails extending frontward and rearwards for engaging with guiding grooves formed at two opposite sides of a fixing base which is surrounded by the slier.

13. The holding mechanism as claimed in claim 12, further comprising a supporting platform, the fixing base is fixed on the supporting platform.
